(19) United States
(12) Patent Application Publication
(10) Pub. No.: US 2002/0102808 A1
(43) Pub. Date: Aug. 1, 2002

(54) Method for raising capacitance of a trench capacitor and reducing leakage current

(76) Inventors: Skyland Pu, Jya-Yi City (TW); Yi-Fan Chen, Taichung City (TW)

Correspondence Address: Powell, Goldstein, Frazer & Murphy, LLP, Suite 600, 101 Pennsylvanic Avenue, Washington, DC, 20004, US

(21) Appl. No.: 09/774,465

(22) Filed: Jan. 31, 2001

(51) Int. Cl. H01L 21/20

(52) U.S. Cl. 438/389

(57) ABSTRACT

A method for forming a dielectric layer with uniform thickness in a trench capacitor comprises providing a substrate structure. A trench device formed in the substrate structure is used as a capacitor and has sidewall and a bottom. Next, the sidewall of the trench device are treated by ion bombardment for forming amorphous structure thereon. Then a dielectric layer, such as an oxide layer, is formed on the sidewall and the bottom of the trench device by CVD or thermal oxidation. To be specific, because of amorphous structure of the sidewall and bottom of the trench device, the dielectric layer can have uniform thickness profile in the trench device.

### BACKGROUND OF THE INVENTION

1. Field of the Invention

The invention relates to a method for forming an oxide layer with uniform thickness in a trench capacitor, and more particularly to a method for raising capacitance and reducing leakage current by uniform thickness oxide layer in the trench capacitor.

2. Description of the Prior Art

Trench-capacitor structures have been developed as a way to achieve DRAM cells with larger capacitance without increasing the area these cells occupy on the chip surface. There are several differences between the trench structures used for isolation and those used as DRAM capacitors. For an isolation device, the insulator film on the trench walls can be relatively thick, and the trench can be refilled with SiO₂ as isolation of the shallow trench. In the latter, the dielectric film formed on the trench walls serves as the dielectric layer of the capacitor, and it must have a thin as well as uniform thickness. Since the material that refills the trench serves as capacitor, it must be in need of high dielectric constant and extensive and ultra-thin area for forming the capacitor. Furthermore, in order for increased capacitance to be obtained through increases in trench depth, the trench walls must be highly vertical and uniform.

Several techniques have been developed for achieving a dielectric capacitor film that in thin enough to provide both high capacitance and high reliability (that is, the dielectric film must be able to provide the same equivalent breakdown voltage as the planar capacitor used in previous DRAM generations, for example one large than 6 MV/cm,). First, composite dielectric films (e.g., ONO structure, that is oxide/nitride/oxide structure) are frequently used. Since the nitride has a higher dielectric constant than SiO₂, a thicker composite film will yield the same capacitance as a thinner single SiO₂ layer. This thicker film prevents capacitor leakage due to tunneling effect.

The growth of the oxide film side to electrode which deposits first is also a key step. Unless preventative measures are taken, the thickness of an oxide layer may not be uniform resulted from the mature of the substrate. Thus, a higher electric field will exist across the dielectric, causing trench capacitors to exhibit higher leakage currents. As depicted in FIG. 1 is a top view of the trench capacitor. Silicon substrate 110 includes an oxide layer 120 formed thereon. In general, the silicon substrate 110 is a single crystal structure and the trench has a cylinder-like shape whose sidewall doesn't have a specific crystalloid surface. In deposited dielectric film, there might grow faster in a specific direction, such as (100), while grow slower in (110) direction. Thus, the growth differences on the structure of the silicon substrate 110 result in non-uniform thickness formation of the oxide layer 120 that is a dielectric layer in the trench capacitor, such as thicker layer at the (100) direction. Furthermore, the non-uniform thickness of the oxide layer 120 may have bad influence on formation of composite ONO film. The main disadvantages of traditional method are to cause capacitance reduction of the trench capacitor and large current leakage on the thinner ONO composite structure.

Accordingly, if there is a method for resolving the influence resulted from crystalloid silicon substrate, the non-uniform thickness of the oxide layer in the trench capacitor structure can be eliminated and the leakage is further reduced. Furthermore, it is helpful for embedded devices and portable apparatus to reduce frequency of refreshing and power consumption with a uniform thickness of the oxide layer.

### SUMMARY OF THE INVENTION

It is an object of the present invention to provide a method for forming a uniform thickness of oxide layer in a trench capacitor. The growth of the oxide layer is independent of substrate structure around the trench capacitor.

It is another object of the present invention to provide a method for forming a uniform thickness of ONO (oxide nitride oxide) structure in a trench capacitor. In the present invention, amorphous silicon structure is formed inside the sidewall of the trench capacitor.

It is a further object of the present invention to provide a method for forming amorphous structure inside the sidewall of a trench capacitor. In the present invention, the amorphous structure is formed by ion bombardment.

In the present invention, a method for forming a dielectric layer with uniform thickness in a trench capacitor comprises providing a substrate structure. A trench device formed in the substrate structure is used as a capacitor and has sidewall and a bottom. Next, the sidewall of the trench device are treated by ion bombardment for forming amorphous structure thereon. Then a dielectric layer, such as an oxide layer, is formed on the sidewall and the bottom of the trench device by deposition process. An extral-finer crystal structure suggested here is to prevent from the preferred growth plane to get an uniform ring around the trench well.

### BRIEF DESCRIPTION OF THE DRAWINGS

A better understanding of the invention may be derived by reading the following detailed description with reference to the accompanying drawing wherein:

FIG. 1 is a top view of a trench capacitor illustrating the thickness profile of the trench capacitor in accordance with the prior art;

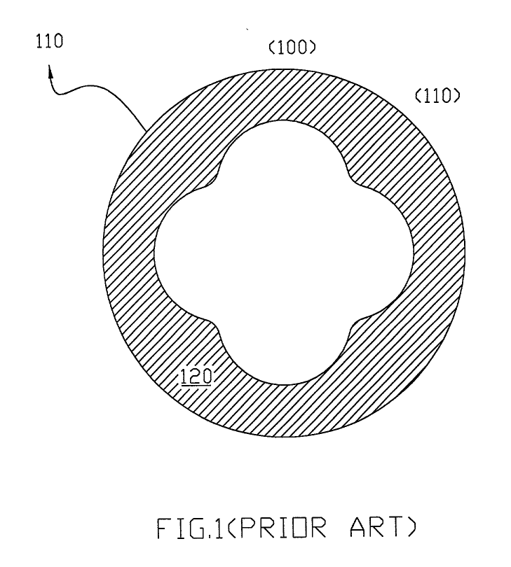

FIGS. 2A-2C are cross-sectional drawings illustrating a method for raising capacitance of the trench capacitor in accordance with the present invention; and

FIG. 3 is a top view of a trench capacitor illustrating the thickness profile of the trench capacitor in accordance with the present invention.

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered and that species and types of substrate and dopant as well as other materials substitutions can be freely made without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method for raising capacitance of a trench capacitor comprises providing a single-crystalline silicon substrate and a trench device is formed therein. The trench device is used as the trench capacitor and has sidewall and a bottom. Next, as a key of the present invention, amorphous structure of the sidewall of the trench device is formed by treating the trench device with ion bombardment and rapid temperature annealing for forming a bottom electrode. Then, a first dielectric layer, such as an oxide layer, is formed on the sidewall and the bottom by CVD or thermal oxidation. Next, a nitride layer, as a part of ONO structure, is formed on the first dielectric layer. Then an oxide layer is deposited on the nitride layer. Next, the trench device is filled with a conductive material, such as doped poly-silicon, as a top electrode of the trench capacitor.

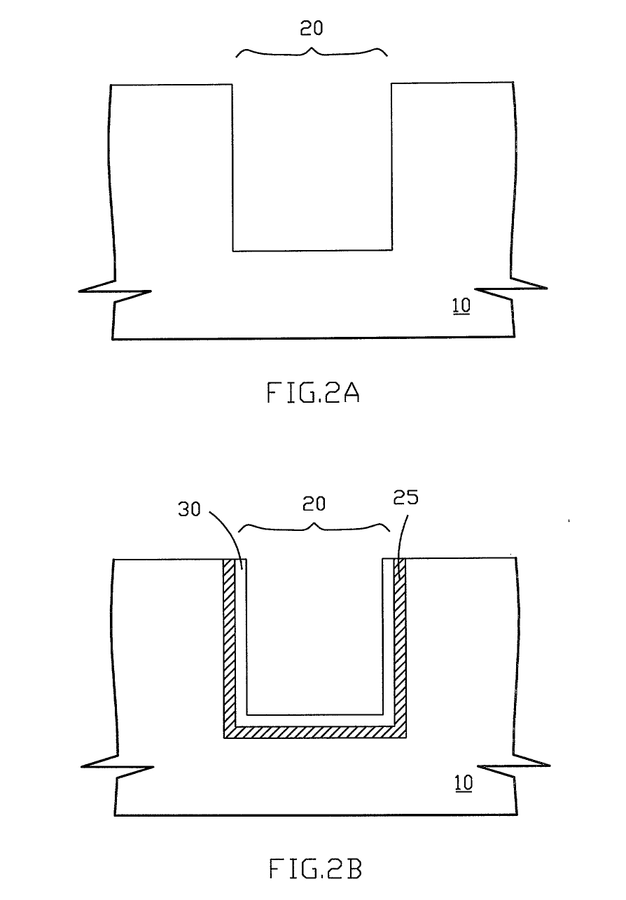

As depicted in FIG. 2A, a silicon substrate 10 is provided and at least a trench structure 20 is formed therein. In the preferred embodiment, the silicon substrate 10 is a typical single-crystalline silicon substrate. The trench structure 20, used as a capacitor, is formed by the conventional dry etching method. It is noted that the inside surface of the trench structure 20 is also the single-crystalline silicon same as the silicon substrate 10.

Next, as a key step of the preferred embodiment is shown in FIG. 2B. Before the formation of ONO structure in the trench structure 20, the inside surface of the trench structure 20 is treated with ion bombardment step. The main purpose of ion bombardment is to destroy the inside structure of the trench structure 20 and the single-crystalline surface so as to form amorphous structure. In the preferred embodiment, the bombardment is implemented in use of arsenic ions as electrode under consideration of lower resistance of arsenic than phosphorus. Furthermore, the operation condition for ion bombardment, such as implanted angle, energy or type of ions, can be adjustable to fit the geometric structure of the trench structure 20 and the requirement on the capacitor.

Then the wafer is placed into furnace for the rapid thermal process (RTP) or rapid temperature annealing (RTA). The main purpose of RTP or RTA is for driving arsenic ions into the trench structure 20 and forming an electrode. The amorphous structure of the trench structure 20 resulted from ion bombardment is used as a bottom electrode 25 of the capacitor by treatment of the rapid tempering process or rapid temperature annealing. Based on uniform amorphous structure of the inside sidewall of the bottom electrode 25, an oxide layer 30, deposited on the outside sidewall of the bottom electrode 25, can have the uniform thickness.

Next, a nitride layer 40 and an oxide layer 50, composed of ONO structure 60, are subsequently deposited on the uniform oxide layer 30. Then the trench structure 20 is filled with doped poly-silicon 70 as a top electrode, shown as FIG. 2C. Because of both the uniform thickness of the oxide layer 30 and large interface of sidewall of the trench structure 20, the nitride layer 40 and oxide layer 50 can also have uniform thickness and further raise the capacitance amount. Furthermore, all the uniform thickness of the oxide film 30, the nitride layer 40, and the oxide layer 50 can prevent the leakage current resulting from the non-uniform thickness of the ONO structure 60 in the trench structure 20. Thus, the retention time can be lengthened and power consumption can be reduced for forming the device of embedded device and portable apparatus.

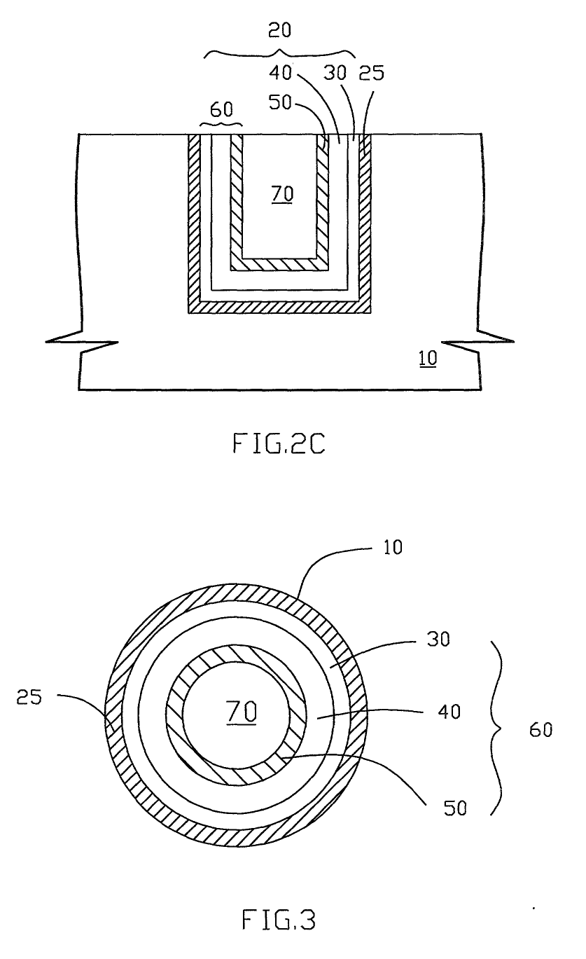

FIG. 3 is a top view of the trench structure 20 in the preferred embodiment. The profile of ONO structure 60 has the uniform thickness for the sidewall of the trench structure 20. That is, the profile distance between the ONO structure 60 and the sidewall of the trench structure 20 is uniform for all of points on the profiles. Thus, the leakage problem resulting from non-uniform thickness can be resolved.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming a dielectric layer with uniform thickness in a trench capacitor, said method comprising:
providing a substrate structure;
forming a trench device in said substrate structure, said trench device as a capacitor having a sidewall and a bottom;
treating said sidewall of said trench device by ion bombardment; and
forming a dielectric layer on said sidewall and said bottom of said trench device.

2. The method according to claim 1, wherein said substrate structure comprises a single-crystalline silicon substrate.

3. The method according to claim 1, wherein said dielectric layer comprises an oxide layer.

4. The method according to claim 1, wherein said trench device is formed by dry-etch method.

5. The method according to claim 1, wherein said treating step comprises using arsenic ions in ion bombardment.

6. The method according to claim 1, wherein said treating step further comprises forming an amorphous structure of said sidewall and said bottom for said trench device.

7. The method according to claim 6, wherein say treating step further comprises treating said amorphous structure by rapid tempering process for forming a bottom electrode.

8. The method according to claim 1, wherein said forming said dielectric layer step is implemented by chemical vapor deposition or thermal oxidation.

9. A method for raising capacitance of a trench capacitor, said method comprising:
providing a single-crystalline silicon substrate;
forming a trench device in said single-crystalline silicon substrate, said trench device as said trench capacitor having a sidewall and a bottom;
forming an amorphous structure of said sidewall;
forming a first dielectric layer on said sidewall and said bottom of said trench device;
depositing a nitride layer on said first dielectric layer;
depositing an oxide layer on said nitride layer; and
filling said trench device with a conductive material to form a top electrode of said trench capacitor.

10. The method according to claim 9, wherein said amorphous structure results from treating said sidewall and said bottom by ion bombardment.

11. The method according to claim 10, wherein said treating step comprises using arsenic ions in ion bombardment.

12. The method according to claim 10, wherein said treating step further comprises driving said arsenic ions into said amorphous structure by rapid temperature annealing.

13. The method according to claim 9, wherein said forming said amorphous structure further comprises treating said amorphous structure by rapid tempering process for forming a bottom electrode of said trench capacitor.

14. The method according to claim 9, wherein said first dielectric layer is formed by chemical vapor deposition or thermal oxidation.

15. The method according to claim 9, wherein said first dielectric layer comprises an oxide layer.

16. The method according to claim 9, wherein said conductive material comprises doped poly-silicon material.

17. A method for reducing leakage current of a trench capacitor, said method comprising:
providing a single-crystalline silicon substrate;
forming a trench device in said single-crystalline silicon substrate, said trench device as said trench capacitor having a sidewall and a bottom;
forming an amorphous structure of said sidewall of said trench device by ion bombardment;
treating said amorphous structure for forming a bottom electrode of said trench capacitor by annealing;
forming a first dielectric layer on said sidewall and said bottom;
depositing a nitride layer on said first dielectric layer;
depositing an oxide layer on said nitride layer; and
filling said trench device with a conductive material to form said trench capacitor for forming a top electrode of said trench capacitor.

18. The method according to claim 17, wherein said forming said amorphous structure comprises using arsenic ions in ion bombardment.

19. The method according to claim 18, wherein said annealing treating step comprises driving in said arsenic ions.

20. The method according to claim 17, wherein said annealing treating step further comprises accomplished by rapid tempering process.

21. The method according to claim 17, wherein said conductive material comprises doped poly-silicon material.
